(19) United States
(12) Patent Application Publication
(10) Pub. No.: US 2026/0001107 A1
(43) Pub. Date: Jan. 1, 2026

(54) ASSEMBLY FOR AN ULTRAVIOLET-OZONE CLEANING SYSTEM

(71) Applicant: KLA Corporation, Milpitas, CA (US)

(72) Inventors: Tara Chan, Ann Arbor, MI (US); Mitchell Faust, Ann Arbor, MI (US); Kira Purvin, Livonia, MI (US); Hongbo Si, Ann Arbor, MI (US); Sylvi Haendel, Milpitas, CA (US); Jason Lerch, Ann Arbor, MI (US); Francis Chilese, San Ramon, CA (US)

(21) Appl. No.: 18/902,872

(22) Filed: Sep. 30, 2024

Related U.S. Application Data
(60) Provisional application No. 63/665,696, filed on Jun. 28, 2024.
(60) Provisional application No. 63/665,674, filed on Jun. 28, 2024.

(51) Int. Cl. B08B 7/00; G01N 21/95; G02B 27/00; G03F 1/22; H01L 21/67

(52) U.S. Cl. CPC B08B 7/0057; G01N 21/9501; G02B 27/0006; G03F 1/22; H01L 21/67288

(57) ABSTRACT

An inspection tool to inspect a reticle includes an assembly with a body that includes concentric channels; a fluid inlet in fluid communication with the body; a fluid outlet in fluid communication with the body; and a printed circuit board having a plurality of LED dies. The printed circuit board is on an end of the body opposite the fluid inlet and the fluid outlet. Ozone is injected into a chamber of the inspection tool around an optical element. The LED dies generate light directed at the optical element. UV-ozone cleaning of the optical element is performed using the light from the LED dies.

### CROSS-REFERENCE TO RELATED APPLICATIONS

This application claims priority to the provisional patent applications filed Jun. 28, 2024 and assigned U.S. App. No. 63/665,674 and U.S. App. No. 63/665,696, the disclosures of which are hereby incorporated by reference.

### FIELD OF THE DISCLOSURE

This disclosure relates to cleaning systems used in tools for semiconductor manufacturing and, more particularly, for inspection tools for semiconductor manufacturing.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices such as logic and memory devices typically includes processing a substrate such as a semiconductor wafer or other workpieces using a large number of semiconductor fabrication processes to form various features and multiple levels of the semiconductor devices. For example, lithography is a semiconductor fabrication process that involves transferring a pattern from a reticle to a resist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

As the demand for lithography-based device structures having ever-smaller features continues to increase, the need for improved illumination sources used for lithography and inspection of the associated reticles that lithographically print these devices continues to grow. One such illumination source, used in lithography and inspection systems, is an extreme ultraviolet (EUV) light source. While shifting the scanner wavelength to EUV has enabled printing of the smaller pattern features required for <5 nm design node chips, it has also added complexity to the equipment, reticles, photoresists, and other infrastructure required to support EUV lithography. New defect mechanisms and tighter patterning and overlay requirements have driven the need for intensive process control strategies as EUV is adopted. With EUV now being used for production of logic chips and in DRAM manufacturing, process control systems are being used to monitor and control many aspects of EUV lithography. EUV process control includes validating the state of EUV reticles.

Reticles, also known as photomasks or masks, contain the pattern information for features printed on wafers. Within a EUV scanner, EUV light reflects from the reticle surface, transferring the pattern from the reticle to the wafer surface. If there is a defect on a reticle, it can potentially print in every chip on the wafer, creating what is called a repeating defect. A repeating pattern error that kills the chips can be catastrophic to yield. To understand reticle quality, a reticle inspection system finds the defects that can cause this impact.

In an inspection system using EUV, maintaining the environment cleanliness can help sustain the mirror reflectivity and the overall EUV photon budget. However, contaminants that tend to foul the vacuum environment cannot be completely removed from the system. Such is the case, for example, when components of the EUV system like adhesives, actuators, and cables contain unavoidable contamination sources. As a result, the EUV optics within the vacuum chamber are exposed to a partial pressure of contaminants, such as hydrocarbons and gas phase H₂O. These contaminants, when exposed to the EUV radiation within the tool, will lead to the growth of carbon and/or oxides on optical surfaces of the system, such as mirrors. In the case of mirrors, the contamination will cause a reflectivity drop and a phase change in the light incident upon the mirror. Both effects, if unchecked, will cause a degradation of the optics over time, leading to a failure of the optical system.

Even with a multi-layer coating technology, each EUV mirror at normal or near normal incidence angle will likely only reflect some of the light. This reflectivity will be lowered by carbon deposition on the optic surfaces caused by the interaction of volatile organic contamination (VOC) with the energetic EUV photons as well as other wavelengths. For example, in an EUV system, vacuum-ultraviolet/ultraviolet (VUV/UV) photons with wavelengths below 300 nm may also be present in the imaging light and cause contaminate deposition.

A method of cleaning deposited carbon includes exposure of a mirror surface to UV light in the presence of ozone molecules. The carbon removal rate is generally proportional to the UV irradiance. Improved systems and techniques are still needed to clean optical elements and ensure proper performance of inspection systems.

### BRIEF SUMMARY OF THE DISCLOSURE

An assembly is provided in a first embodiment. The assembly includes a body that includes concentric channels therein; a fluid inlet in fluid communication with the body; a fluid outlet in fluid communication with the body; and a printed circuit board having a plurality of LED dies. The printed circuit board is disposed on an end of the body opposite the fluid inlet and the fluid outlet.

An inner one of the concentric channels can be in fluid communication with the fluid inlet and an outer one of the concentric channels can be in fluid communication with the fluid outlet.

The assembly can include a gas inlet and a gas outlet in fluid communication with the body. The gas inlet may be an ultraTorr gas inlet. In an instance, the assembly includes a re-entrant tube disposed around the body. The re-entrant tube defines a gap between the re-entrant tube and the body. The gap is in fluid communication with at least the gas inlet.

The body can be configured to provide impinging flow liquid cooling.

A system is provided in a second embodiment. The system includes an inspection tool configured to inspect a reticle and an assembly. The assembly includes a body that includes concentric channels therein; a fluid inlet in fluid communication with the body; a fluid outlet in fluid communication with the body; and a printed circuit board having a plurality of LED dies. The printed circuit board is disposed on an end of the body opposite the fluid inlet and the fluid outlet.

An inner one of the concentric channels can be in fluid communication with the fluid inlet and an outer one of the concentric channels can be in fluid communication with the fluid outlet.

The assembly can include a gas inlet and a gas outlet in fluid communication with the body. The gas inlet may be an ultraTorr gas inlet. In an instance, the assembly includes a re-entrant tube disposed around the body. The re-entrant tube defines a gap between the re-entrant tube and the body. The gap is in fluid communication with at least the gas inlet.

The body can be configured to provide impinging flow liquid cooling.

A method is provided in a third embodiment. The method includes providing an assembly disposed in an inspection tool. The assembly includes a body that includes concentric channels therein; a fluid inlet in fluid communication with the body; a fluid outlet in fluid communication with the body; and a printed circuit board having a plurality of LED dies. The printed circuit board is disposed on an end of the body opposite the fluid inlet and the fluid outlet. Ozone is injected into a chamber of the inspection tool around an optical element. Light is generated and directed at the optical element in the inspection tool using the LED dies. UV-ozone cleaning of the optical element is performed using the light from the LED dies.

The light may be UV radiation.

The method can include flowing a coolant from the fluid inlet, through the body, and through the fluid outlet. The coolant may be propylene glycol. The flowing can provide impinging flow liquid cooling.

The method can include flowing an inert gas around the assembly thereby forming a protective shroud around at least part of the assembly.

### DESCRIPTION OF THE DRAWINGS

For a fuller understanding of the nature and objects of the disclosure, reference should be made to the following detailed description taken in conjunction with the accompanying drawings, in which:

FIG. 1 is a block diagram of a UV-ozone (UVO) cleaning system in accordance with the present disclosure;

FIG. 2 is an exploded diagram of an embodiment of the assembly of FIG. 1 in accordance with the present disclosure;

FIG. 3 is a cross-sectional diagram showing a heat exchanger in the body of FIG. 2;

FIG. 4 is a diagram showing an embodiment of the assembly of FIG. 1 installed in a wall of the chamber;

FIG. 5 is another cross-sectional diagram showing the heat exchanger in the body of FIG. 2;

FIG. 6 is a perspective view of an embodiment of the assembly of FIG. 2;

FIG. 7 is another cross-sectional diagram showing the heat exchanger in the body of FIG. 2; and

FIG. 8 is another perspective view of an embodiment of the assembly of FIG. 2.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein provide a compact assembly that can perform UVO cleaning on surfaces with carbon deposition in a sensitive, crowded environment using ozone and deep ultraviolet (DUV) LEDs. UVO cleaning can decontaminate hydrocarbons from, for example, a reflective optical surface. Hydrocarbons tend to be highly absorbing in the DUV region. Cleaning methods that incorporate UV radiation with ozone have been shown to be successful when dealing with hydrocarbons. Low-energy plasma cleaning containing an Ar and O₂ gas mixture within the vacuum chamber prior to film deposition can further remove both molecular and particulate contamination from the optical surface. The in-situ cleaning process avoid recontamination issues and improve film adhesion to the substrate surface.

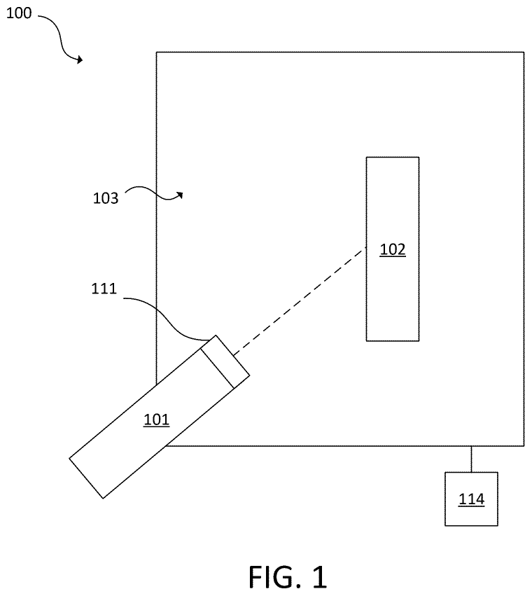

FIG. 1 is a block diagram of a UV-ozone (UVO) cleaning system 100. An assembly 101 includes one or more LEDs 111 that can illuminate a sensitive surface of an optical component 102. The optical component 102 may be, for example, a mirror, an optical filter, or a pellicle. The assembly 101 and optical component 102 are in an environment of a chamber 103, which can be a clean, low-pressure environment. For example, the environment can be an ultraclean, vacuum environment. While only one assembly 101 is illustrated, the UVO cleaning system 100 can include two, three, or more assemblies 101. If more than one assembly 101 is used, then the assemblies 101 may be arrayed to all illuminate the sensitive surface of the optical component 103. The assemblies 101 can illuminate the same point, different non-contiguous points, or overlapping points on the sensitive surface. The illumination can be configured to be relatively uniform, which reduces the risk of uneven cleaning on the optical component 102. Non-uniform cleaning can degrade reflectivity or other optical properties of the optical component 102, which may affect the resulting beam.

The assembly 101 can include one or more LEDs 111. The LEDs 111 can generate DUV wavelengths directed toward a surface of the optical component 102. The LEDs 111 may be in an array, such as an array with a split circuit design for power distribution optimization. The assembly 101 can have a compact shape and size to reduce size constraints. As described in the embodiments disclosed herein, the assembly 101 also can provide impinging flow liquid cooling for the LEDs 111 using a heat exchanger. The heat exchanger may use re-entrant tubes.

During operation, ozone from the ozone source 114 is injected into the environment of the chamber 103. An optional flow of an inert gas (e.g., N₂) or clean dry air with a coolant (e.g., propylene glycol) can be activated. The inert gas can provide a protective shroud around critical optics (e.g., an LED lens and re-entrant tube window) to minimize degradation from oxidation and moisture. The coolant can be used in the heat exchanger of the assembly 101. The LED or LEDs 111 of the assembly 101 can be activated to illuminate the contaminated surface of the optical component 102 with DUV. This enables cleaning of the optical component 102 via surface decarbonization. After cleaning is complete, the LED or LEDs 111 are turned off. The ozone flow is stopped, and other fluids can be turned off. The environment can be pumped down and restored to a normal operating environment.

The assembly 101 can fit within a limited space while still enabling high-power cleaning. For example, the assembly 101 can fit in a standard KF40 vacuum flange. In another example, the assembly 101 can fit within a chamber port that has a 38 mm diameter and is 62 mm long. The heat exchanger of the assembly 101 can provide compact cooling. The LED or LEDs 111 can cover a large surface area of the optical component 102 relative to their location. Placement of the assembly 101 is flexible because, for example, a re-entrant tube can place the LED light source close to the optical surface that requires cleaning, delivering optical power to the contaminated surface. The re-entrant tube also provides air-vacuum isolation to minimize contamination. The LEDs can be configured to tune the DUV radiation. Also, the main components of the UVO cleaning system 100, such as a gas source, fluid source, or power source, are kept outside the chamber 103, which can reduce contamination of the chamber 103.

The re-entrant tube can connect an outside environment to an inside environment and extends into the chamber 103. A bottom of the re-entrant tube can include a window that allows DUV light to enter without adding a DUV light source in the vacuum environment. The re-entrant tube can bring air-side components into vacuum, which can position these components closer to what is being cleaned. This increases the power incident on a cleaned surface while keeping contaminants out.

In an embodiment, a fiber-coupled laser is used instead of the LEDs in the assembly 101. Each assembly 101 may include a lens and fiber subassembly to provide the illumination. The laser source may be positioned outside the chamber 103. The position of the assembly 101 or associated lens can be configured to the fiber's illumination cone. In an embodiment with the fiber-coupled laser, the assembly 101 can use a heat exchanger. In another embodiment with the fiber-coupled laser, the assembly 101 does not use a heat exchanger.

In an embodiment, a linear actuator is used to lower the optical component 102 into the environment of the chamber 103. The assembly 101 can use one or more LEDs or a fiber-coupled laser. This embodiment of the assembly 101 may still use a heat exchanger.

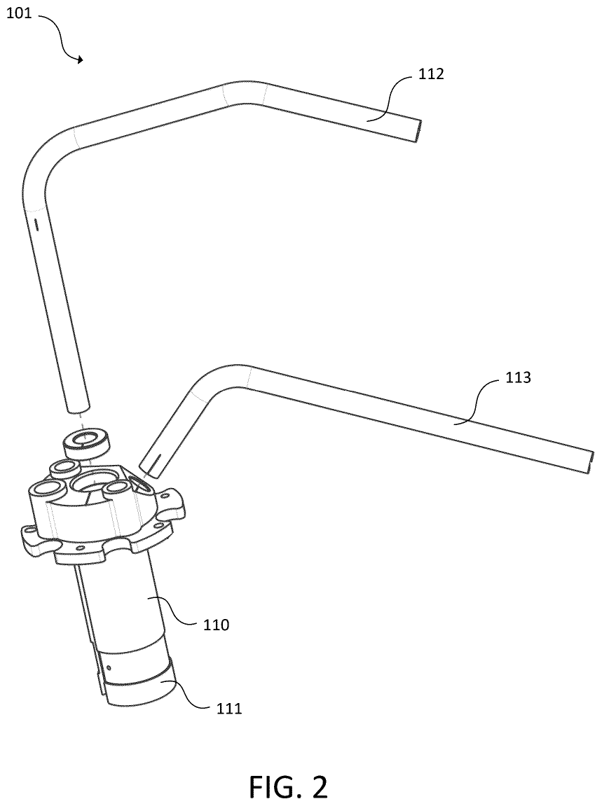

FIG. 2 is a diagram of an embodiment of the assembly 101. The assembly 101 enables LED or other illumination source placement with a small form factor. The impinging flow technique (e.g., impinging jet cooling) used in the assembly 101 can maximize heat transfer at the illumination source (e.g., the LED die surface or surfaces) while minimizing an amount of cooling fluid pressure. Impinging jet cooling can spray a fluid onto a surface to be cooled. The liquid coolant may be, for example, propylene glycol, water, and/or ethylene glycol, though other coolants are possible. In an embodiment, 25% propylene glycol and 75% water is used as a coolant, though other ratios are possible. Liquid coolant can provide enhanced cooling compared to heat sinks. The assembly 101 can serve as a structure support and provide a mounting surface for the printed circuit board that includes the LED array.

The parameters of the impinging jet cooling can be determined based on fluid velocity, inlet temperature, and/or flow geometry. The fluid temperature for incoming liquid coolant may be constant for this determination. For example, the fluid velocity can be approximately 5 m/s without degrading the tubing materials.

The pressure loss may be configured to avoid large or expensive pumping systems for the cooling fluid. The pressure loss also may be configured to reduce risk of breaking a window or seal in the assembly 101. For example, the maximum pressure loss may be 3.77 psi for the assembly 101. A pressure drop across the heat exchangers less than this value can ensure a desired flow rate.

The assembly 101 has a body 110 that includes the heat exchanger. An LED array 111 on a printed circuit board is positioned at an end of the body 110. The body 110 is connected to conduits that serve as a fluid inlet 112 and fluid outlet 113. The heat exchanger can remove heat generated by the LED array 111. For example, up to 120 W or up to 200 W of heat can be removed from each LED.

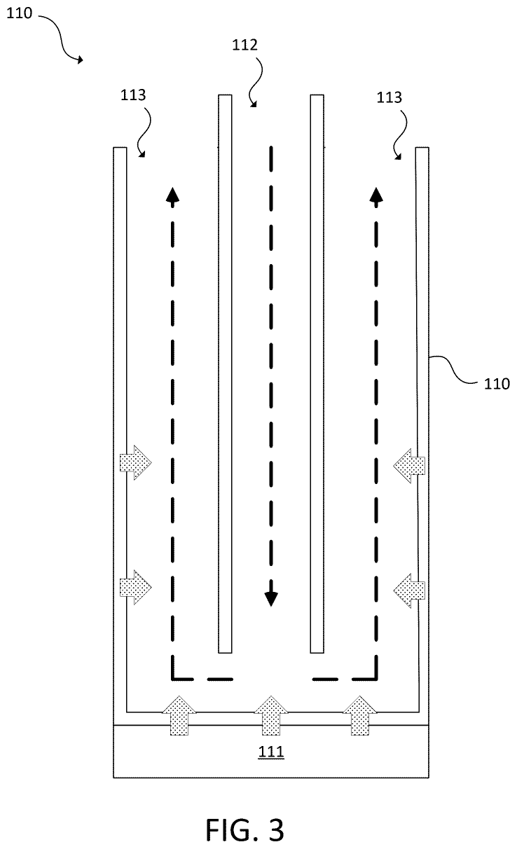

FIG. 3 is a diagram showing the heat exchanger in the body 110 with the fluid inlet 112 and fluid outlet 113. The fluid inlet 112 and fluid outlet 113 may have an outer diameter from ⅛ inch to 2 inches. For example, the fluid inlet 112 and fluid outlet 113 may have an outer diameter of ⅜ inches or less. Fluid flow is shown with the dotted arrows. There may be annular flow within the body 110, such as in the fluid outlet 113. Heat transfer is shown with the shaded arrows. There is annular convection and annular conduction along the sides of the body 110. Impingement convection occurs proximate the LED array 111. The singular impinging flow provides cooling of the LED array 111. Geometric ratios for impinging height-to-inlet diameter, annular diameters, and/or conductive wall thicknesses to annular hydraulic diameters can be configured to meet cooling specifications. The body 110 and other components of the assembly 101 can be stainless steel, copper, aluminum, or other materials.

To optimize heat transfer fluid, surface area near the LED and throughout the annular region of the heat exchanger may be maximized. Creating turbulent flow with an impinging geometry can provide better convection properties. Overall, optimal cooling can include maximizing the allowable heat removal while remaining beneath an LED maximum temperature.

The embedded tube of the assembly 101 can be held by brazing or bolting. Components of the assembly 101 can be fabricated of copper or aluminum, though other materials are possible. The channel tube of the assembly 101 can be welded or 3D printed. Microchannel cavities, porous materials, or additional heat pipes also can be included. These features can be used to supplement or replace an impinging flow design.

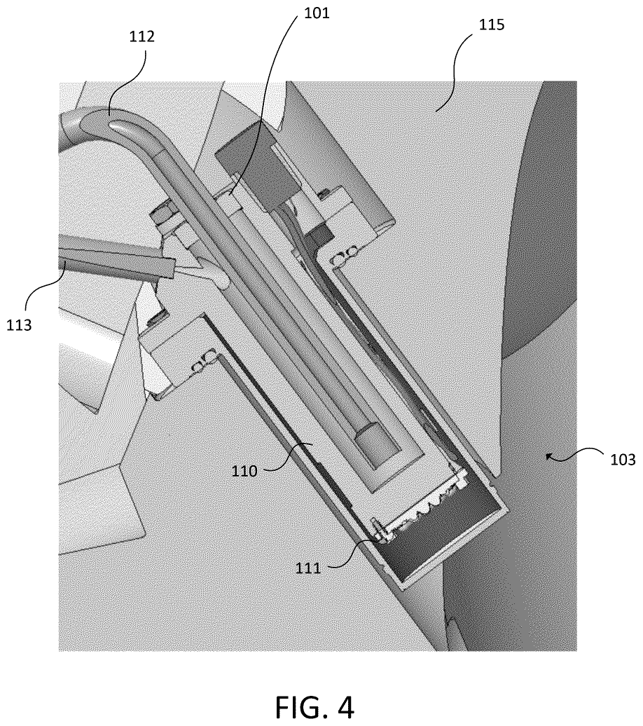

FIG. 4 is a diagram showing an embodiment of the assembly 101 installed in a wall 115 of a chamber 103. The LED array 111 can be directed at an element in the chamber 103. While illustrated in a wall 115, the assembly 101 can be installed in a holding clamp or other surface in or around the chamber 103. There can be a vacuum seal formed between the re-entrant tube and the chamber 103.

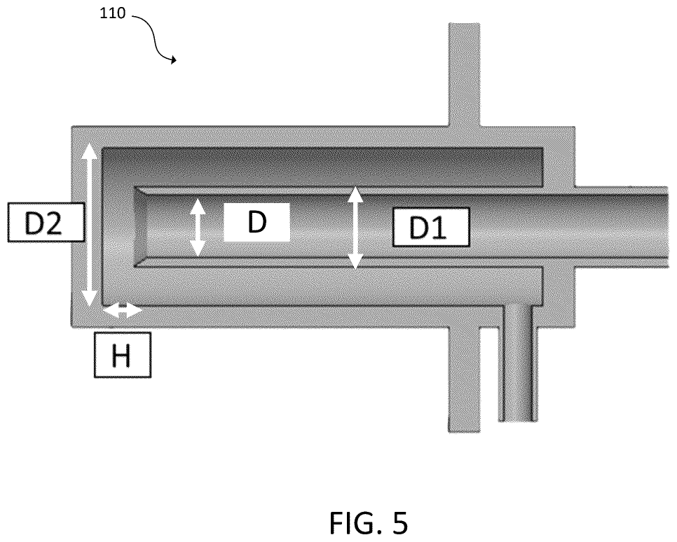

FIG. 5 is another cross-sectional diagram showing the heat exchanger in the body 110. The H/D ratio can range from 1 to 0.3 (e.g., 0.5). The D2/D1 ratio can range from 1.5 to 2.2 (e.g., 1.57 or 1.96). The D is the inner diameter of the inlet tube. D1 is the outer diameter of the inlet tube. D2 is an outer diameter of the outlet tube. H is a distance between the inlet tube and a base of the outlet tube. These ratios can be optimized for maximum heat transfer. However, other values are possible for these ratios and these disclosed ratios are merely examples. As seen in FIG. 5, the bores in the body 110 are cylindrical and one is concentric within the other.

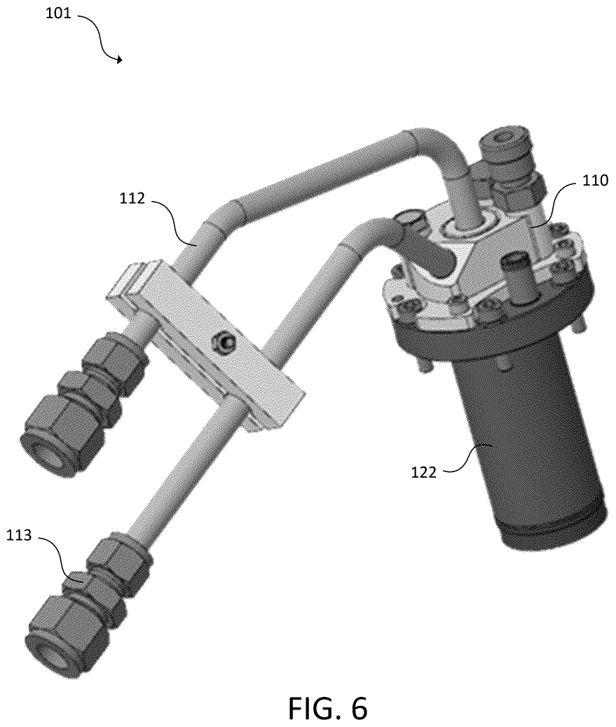

FIG. 6 is a perspective view of an embodiment of the assembly 101. While shown in one configuration, the fluid inlet 112 and fluid outlet 113 can be positioned in other locations on the body 110. The fluid inlet 112 and fluid outlet 113 are illustrated as angled, but can be positioned at a right angle or in other configurations depending on the space constraints of the overall system. A re-entrant tube 122 also is included in the assembly 101.

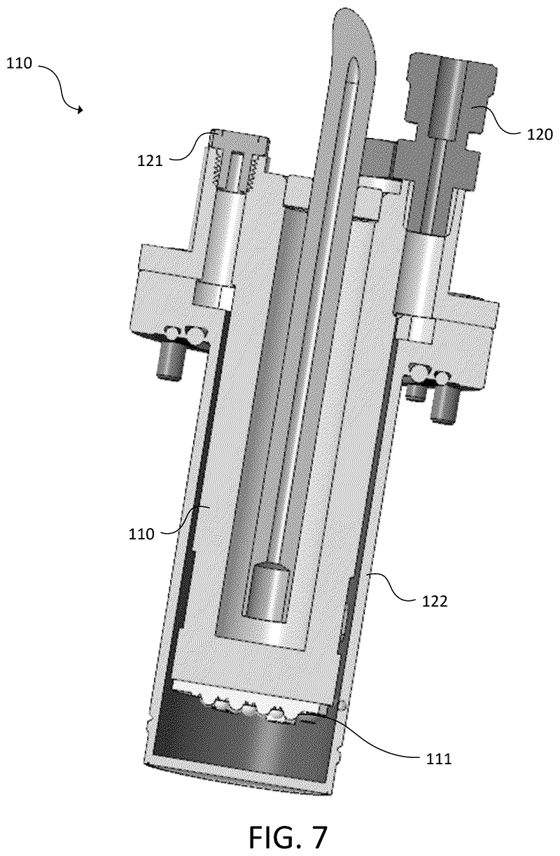

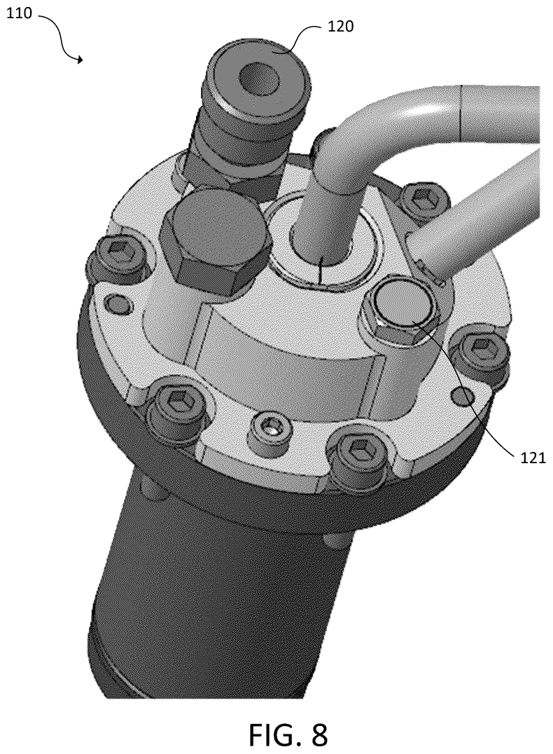

FIG. 7 is another cross-sectional diagram showing the heat exchanger in the body 110. FIG. 8 is another perspective view of an embodiment of the body 110. Components of the body 110 can be selected to ensure gas flow and light tightness. UltraTorr fittings 120 may be used for cleanliness. These fittings 120 may include a quick disconnect. For example, a stainless steel ¼-inch UltraTorr vacuum fitting with a male connector may be used. This may be a ⅛ inch to ¼-inch NPT tube fitting. Other size fittings are possible depending on space constraints of the overall system.

A sintered filter 121 can permit gas to escape without light penetration. The sintered filter can be a ⅛-inch NPT sintered filter, which is light-tight. These components can help provide enhanced lifetime of optical surfaces without degradation. Without a dry inert gas purge (e.g., nitrogen) or clean dry air, there may be negative effects of UV LED interaction with oxygen and water in the cavity. The embodiment of FIG. 7 can block harmful UV irradiation from escaping illumination chamber while allowing purging gas flow. Gas flows through the UltraTorr fitting 120. The ultraTorr fitting 120 can be part of a gas inlet. This gas may be an inert gas or clean dry air. The sintered filter 121 can be part of a gas outlet. Thus, the fluid inlet and outlet can be a distance away from any optical surfaces. The gas flows between the outside of the heat exchanger and the inside of the re-entrant tube. Thus, gas can flow between an outside of the body 110 and an inside of the re-entrant tube 122. A gap is formed between the body 110 and the re-entrant tube 122 to enable the gas flow. The gap can be in fluid communication with the sintered filter 121 and/or the ultraTorr fitting 120. The gas can flow around the LEDs 111.

The UVO cleaning system 100 may be used in an inspection tool that performs inspection on a reticle or other workpiece. Inspection techniques described herein may be applied with respect to any suitable type of reticle or photomask. In one example, an EUV lithography process uses an EUV type reticle that is designed to facilitate patterning on a wafer at EUV wavelengths, such as 13.5 nm. An EUV reticle may generally include a substrate, such a low thermal expansion (LTE) or ultra-low expansion (ULE) glass plate, such as fused silica. The substrate is covered with multiple layers of materials to provide moderate reflectance (e.g., 60-70% or more) at the EUV wavelength for performing lithographic exposure at EUV wavelengths. The multilayer (ML) stack serves as a Bragg reflector that maximizes the reflection of EUV radiation while being a poor absorber of the EUV radiation. Reflection generally occurs at interfaces between materials of different indices of refraction with higher differences causing more reflectivity. Although indices of refraction for materials exposed to wavelengths that are extremely low are about equal to 1, reflection can be achieved through use of multiple layers having alternating layers of different refractive indices. The multilayer stack comprises low absorption characteristics so that the impinging radiation is reflected with little loss.

The multiple layers may include a capping layer, such as Ru, to prevent oxidation. In other embodiments, an EUV reticle may include a quartz, antireflective coating (ARC), and other features. A pattern is formed in an absorber layer that is disposed over the multiple layers. The material(s) used for the reticle pattern may be selected to have nearly zero etch bias so as to achieve ultra-fine resolution features.

Besides an EUV type reticle, the terms “reticle” and “photomask” may also include a transparent substrate, such as glass, borosilicate glass, quartz, or fused silica having a layer of opaque material formed thereon. The opaque (or substantially opaque) material may include any suitable material that completely or partially blocks photolithographic light (e.g., deep UV). Example materials include chrome, molybdenum silicide (MoSi), tantalum silicide, tungsten silicide, opaque MoSi on glass (OMOG), etc. A polysilicon film may also be added between the opaque layer and transparent substrate to improve adhesion. A low reflective film, such as molybdenum oxide (MoO₂), tungsten oxide (WO₂), titanium oxide (TiO₂), or chromium oxide (CrO₂) may be formed over the opaque material.

The term reticle may refer to different types of reticles including, but not limited to, a clear-field reticle, a dark-field reticle, a binary reticle, a phase-shift mask (PSM), an alternating PSM, an attenuated or halftone PSM, a ternary attenuated PSM, or a chromeless phase lithography PSM. A clear-field reticle has field or background areas that are transparent, and a dark-field reticle has field or background areas that are opaque. A binary reticle is a reticle having patterned areas that are either transparent or opaque. For example, a photomask made from a transparent fused silica blank with a pattern defined by a chrome metal adsorbing film can be used. Binary reticles are different from phase-shift masks (PSM), one type of which may include films that only partially transmit light, and these reticles may be commonly referred to as halftone or embedded phase-shift masks (EPSMs). If a phase-shifting material is placed on alternating clear spaces of a reticle, the reticle is referred to as an alternating PSM, an ALT PSM, or a Levenson PSM. One type of phase-shifting material that is applied to arbitrary layout patterns is referred to as an attenuated or halftone PSM, which may be fabricated by replacing the opaque material with a partially transmissive or “halftone” film. A ternary attenuated PSM is an attenuated PSM that includes completely opaque features as well.

The defectivity control of the EUV photomasks, which defines the patterns printed on semiconductor wafers or other workpieces, plays a role from a process yield management perspective. However, defect detection has been regarded as one of the risks of EUV lithography development due to the lack of an actinic EUV photomask inspector that optically inspects the photomask at the same wavelength as the EUV scanner uses (e.g., 13.5 nm). Electron-beam inspection tools, which potentially can offer a good sensitivity, typically have an inspection throughput that is orders of magnitude slower than what is desired and, therefore, are not usually a practical solution for full mask inspection. Currently, and for the foreseeable future, the inspection of patterned EUV photomasks will rely on the more available, higher throughput inspection tools operating within the deep-UV (DUV) wavelength range (190-260 nm).

While described with respect to an inspection tool and UVO cleaning, the embodiments disclosed herein can be used in other systems or for other applications.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. An assembly comprising:
a body that includes concentric channels therein;
a fluid inlet in fluid communication with the body;
a fluid outlet in fluid communication with the body; and
a printed circuit board having a plurality of LED dies, wherein the printed circuit board is disposed on an end of the body opposite the fluid inlet and the fluid outlet.

2. The assembly of claim 1, wherein an inner one of the concentric channels is in fluid communication with the fluid inlet and an outer one of the concentric channels is in fluid communication with the fluid outlet.

3. The assembly of claim 1, further comprising a gas inlet and a gas outlet in fluid communication with the body.

4. The assembly of claim 3, wherein the gas inlet is an ultraTorr gas inlet.

5. The assembly of claim 3, further comprising a re-entrant tube disposed around the body, wherein the re-entrant tube defines a gap between the re-entrant tube and the body, and wherein the gap is in fluid communication with at least the gas inlet.

6. The assembly of claim 1, wherein the body is configured to provide impinging flow liquid cooling.

7. A system comprising:
an inspection tool configured to inspect a reticle; and
an assembly that includes:
a body that includes concentric channels therein;
a fluid inlet in fluid communication with the body;
a fluid outlet in fluid communication with the body; and
a printed circuit board having a plurality of LED dies, wherein the printed circuit board is disposed on an end of the body opposite the fluid inlet and the fluid outlet.

8. The system of claim 7, wherein an inner one of the concentric channels is in fluid communication with the fluid inlet and an outer one of the concentric channels is in fluid communication with the fluid outlet.

9. The system of claim 7, further comprising a gas inlet and a gas outlet in fluid communication with the body.

10. The system of claim 9, wherein the gas inlet is an ultraTorr gas inlet.

11. The system of claim 9, further comprising a re-entrant tube disposed around the body, wherein the re-entrant tube defines a gap between the re-entrant tube and the body, and wherein the gap is in fluid communication with at least the gas inlet.

12. The system of claim 7, wherein the body is configured to provide impinging flow liquid cooling.

13. A method comprising:
providing an assembly disposed in an inspection tool, wherein the assembly includes:
a body that includes concentric channels therein;
a fluid inlet in fluid communication with the body;
a fluid outlet in fluid communication with the body; and
a printed circuit board having a plurality of LED dies, wherein the printed circuit board is disposed on an end of the body opposite the fluid inlet and the fluid outlet;
injecting ozone into a chamber of the inspection tool around an optical element;
generating light directed at the optical element in the inspection tool using the LED dies; and
performing UV-ozone cleaning of the optical element using the light from the LED dies.

14. The method of claim 13, wherein the light is UV radiation.

15. The method of claim 13, further comprising flowing a coolant from the fluid inlet, through the body, and through the fluid outlet.

16. The method of claim 15, wherein the coolant is propylene glycol.

17. The method of claim 15, wherein the flowing provides impinging flow liquid cooling.

18. The method of claim 13, further comprising flowing an inert gas around the assembly thereby forming a protective shroud around at least part of the assembly.
